(19) United States
(12) Patent Application Publication
(10) Pub. No.: US 2021/0104439 A1
(43) Pub. Date: Apr. 8, 2021

(54) MEMORY DEVICE AND METHOD FOR FABRICATING THE SAME

(71) Applicant: MACRONIX INTERNATIONAL CO., LTD., Hsinchu (TW)

(72) Inventors: Shaw-Hung KU, Hsinchu City (TW); Cheng-Hsien CHENG, Yunlin County (TW); Wen-Jer TSAI, Hualien City (TW)

(21) Appl. No.: 16/592,923

(22) Filed: Oct. 4, 2019

(51) Int. Cl. H01L 21/8234; H01L 27/11582

(52) U.S. Cl. CPC H01L 21/823481; H01L 21/823487; H01L 27/11582

(57) ABSTRACT

A memory device includes a substrate, a stacked structure, a plurality of channel structures, a plurality of memory layers, and a plurality of shallow isolation structures. The substrate has an upper surface. The stacked structure is disposed on an upper surface of the substrate, wherein the stacked structure includes a plurality of insulating layers and a plurality of conductive layers alternatively stacked on the upper surface. The channel structures penetrate portions of the stacked structure and are electrically connected to the substrate. The memory layers surround the corresponding ones of the channel structures. The shallow isolation structures extend from a top surface of the stacked structure toward the substrate, wherein each of the shallow isolation structures includes a substance having a dielectric constant of less than 3.9.

### BACKGROUND

### Field of the Invention

The disclosure relates in general to a semiconductor structure and a method for fabricating the same, and more particularly to a memory device and a method for fabricating the same.

### Description of the Related Art

Recently, as the demand for more excellent memory devices has gradually increased, various three-dimensional (3D) memory devices have been provided, such as 3D NAND memory devices or 3D ROM memory devices. Such 3D memory devices can achieve higher storage capacity and have superior electronic characteristics, such as good data storage reliability and operation speed.

During fabricating the 3D memory device, a plurality of common source lines electrically connected to the substrate are required to be formed, and to divide the 3D memory device into a plurality of blocks and sub-blocks. However, an excessive number of common source lines may cause the size of the 3D memory device to become larger.

Therefore, there is a need to propose an advanced memory device and a method of fabricating the same to solve the problems faced by the prior art.

### SUMMARY OF THE INVENTION

In the present disclosure, a memory device and a method for fabricating the same are provided to solve at least some of the above problems.

According to an embodiment of the disclosure, a memory device includes a substrate, a stacked structure, a plurality of channel structures, a plurality of memory layers, and a plurality of shallow isolation structures. The substrate has an upper surface. The stacked structure is disposed on an upper surface of the substrate, wherein the stacked structure includes a plurality of insulating layers and a plurality of conductive layers alternatively stacked on the upper surface. The channel structures penetrate portions of the stacked structure and are electrically connected to the substrate. The memory layers surround the corresponding ones of the channel structures. The shallow isolation structures extend from a top surface of the stacked structure toward the substrate, wherein each of the shallow isolation structures includes a substance having a dielectric constant of less than 3.9

According to an embodiment of the disclosure, a method for fabricating a memory device includes the following steps. Firstly, a substrate is provided, and the substrate has an upper surface. Then, a stacked structure is formed on the upper surface of the substrate, wherein the stacked structure includes a plurality of insulating layers and a plurality of conductive layers stacked on the upper surface of the substrate. A plurality of channel structures and a plurality of memory layers penetrating the stacked structure are formed, the channel structures are electrically connected to the substrate, and the memory layers surround the corresponding ones of the channel structures. Thereafter, a plurality of upper openings are formed penetrating an upper portion of the stacked structure. A plurality of shallow isolation structures are formed in the upper opening, the shallow isolation structures extends from a top surface of the stacked structure toward the substrate, wherein each of the shallow isolation structures includes a substance having a dielectric constant of less than 3.9.

According to an embodiment of the disclosure, a method for fabricating a memory device includes the following steps. Firstly, a substrate is provided, and the substrate has an upper surface. A stacked body is formed on the upper surface of the substrate, wherein the stacked body includes a plurality of insulating layers and a plurality of sacrificial layers alternatively stacked on the upper surface of the substrate. A plurality of channel structures and a plurality of memory layers are formed penetrating the stacked body. The channel structures are electrically connected to the substrate, and the memory layers surrounds the corresponding ones of the channel structures. A plurality of vertical openings are formed penetrating the stacked body. The sacrificial layers are removed through the vertical openings. A plurality of conductive layers are formed at locations where the sacrificial layers are removed, such that the plurality of conductive layers and the plurality of insulating layers alternatively stacked on the upper surface form a stacked structure. A plurality of upper openings are formed penetrating an upper portion of the stacked structure. A plurality of shallow isolation structures are formed in the upper openings, the shallow isolation structures extending from a top surface of the stacked structure toward the substrate, wherein each of the shallow isolation structures includes a substance having a dielectric constant of less than 3.9

In order to better understand the above and other aspects of the present disclosure, the following detailed description of the embodiments and the accompanying drawings are set forth below. However, the scope of the disclosure is defined by the scope of the appended claims.

### BRIEF DESCRIPTION OF THE DRAWINGS

FIG. 1A is a top view of a memory device in accordance with an embodiment of the present disclosure.

FIG. 1B is a cross-sectional view of a memory device in accordance with an embodiment of the present disclosure taken along line A-A′ of FIG. 1.

FIGS. 2A to 2F are cross-sectional views showing a method for fabricating a memory device in accordance with an embodiment of the present disclosure.

FIG. 3 is a cross-sectional view of a memory device in accordance with another embodiment of the present disclosure.

FIGS. 4A to 4F are cross-sectional views showing a method for fabricating a memory device according to still another embodiment of the present disclosure.

FIG. 5 is a cross-sectional view of a memory device in accordance with a further embodiment of the present disclosure.

### DETAILED DESCRIPTION OF THE INVENTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

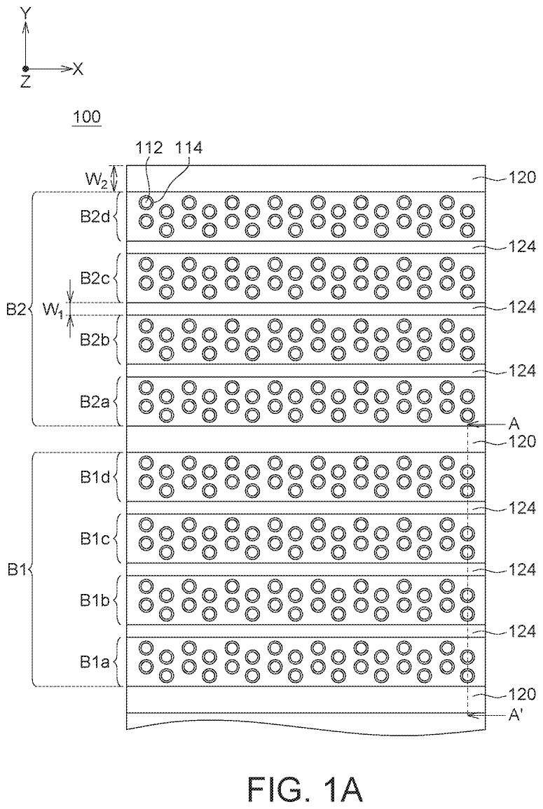

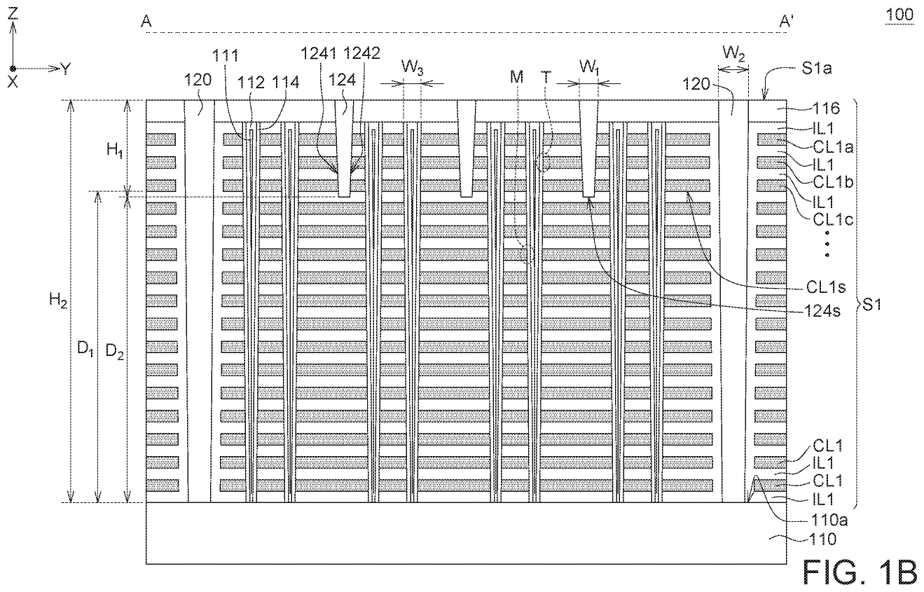

FIG. 1A is a top view of a memory device 100 according to an embodiment of the present disclosure. FIG. 1B is a cross-sectional view of a memory device 100 according to an embodiment of the present disclosure taken along line A-A′ of FIG. A.

Referring to FIG. 1A, a plurality of conductive connecting structures 120 extend along a first direction (eg, an X-axis direction) parallel to an upper surface 110a of a substrate 110 (shown in FIG. 1B), and the memory device 100 is divided into a plurality of blocks B1, B2, . . . Each of the blocks B1, B2 . . . includes a plurality of shallow isolation structures 124. The shallow isolation structures 124 divide the block B1 into a plurality of sub-blocks B1a, B1b, B1c, B1d, and divide the block B2 into a plurality of sub-blocks B2a, B2b, B2c, B1d. In this embodiment, there are three shallow isolation structures 124 in each block, but the disclosure is not limited thereto. In other embodiments, there may be 2 or more than 3 shallow isolation structures in each block. In some embodiments, the electrically conductive connecting structure 120 is a common source line.

Referring to FIGS. 1A and 1B simultaneously, the memory device 100 includes a substrate 110, a stacked structure S1, a plurality of channel structures 112, a plurality of insulating posts 111, a plurality of memory layers 114, a plurality of shallow isolation structures 124, and a plurality of conductive connecting structures 120. The stacked structure S1 is formed on the upper surface 110a of the substrate 110. The stacked structure S1 includes a plurality of insulating layers IL1 and a plurality of conductive layers CL1 alternatively stacked (for example, along the Z axis) on the upper surface 110a of the substrate 110, and a cap layer 116 on the top portion of the stacked structure S1.

In some embodiments, substrate 110 can be a silicon substrate or other suitable substrate. The insulating layer IL1 and the cap layer 116 may be formed of an oxide such as silicon dioxide (SiO₂). In some embodiments, the material of the cap layer 116 may be the same as the material of the insulating layer IL1. The conductive layer CL1 may be formed of a conductive material such as tungsten (W), aluminum (Al), titanium nitride (TiN), tantalum nitride (TaN), doped or undoped poly-silicon (poly-silicon).) or other suitable materials.

The numbers of the insulating layers and the conductive layers are exemplarily illustrated in the embodiments of the present disclosure, but the present disclosure is not limited thereto. In some embodiments, the numbers of the insulating layers and the conductive layers may be any suitable number.

The conductive connecting structures 120 penetrate (eg, along the Z-axis) the stacked structure S1 and are electrically connected to the substrate 110. The conductive connecting structures 120 divide the memory element 100 into a plurality of blocks B1, B2, . . . The conductive layers CL1 between the different blocks B1, B2, . . . are completely separated by the conductive connecting structures 120.

The channel structures 112 penetrate (eg, along the Z-axis) portions of the stacked structure S1 and are electrically connected to the substrate 110. The top of the channel structure 112 can be electrically connected to a bit line (not shown). In some embodiments, the channel structure 112 can be formed of a semiconductor material, such as a doped or undoped polysilicon. In some embodiments, the insulating posts 111 penetrate portions of the stacked structure S1, for example, along Z-axis, and are surrounded by the channel structures 112.

The memory layers 114 surround the corresponding channel structures 112. In some embodiments, the memory layer 114 can be composed of a composite layer (ie, an ONO layer) comprising a silicon oxide layer, a silicon nitride layer, and a silicon oxide layer.

In some embodiments, the conductive connecting structures 120 and the shallow isolation structures 124 respectively extend along a first direction (eg, X-axis direction) and disposed along a second direction (eg, Y-axis direction) on the substrate 110, the first direction and the second direction are both parallel to the upper surface 110a of the substrate 110, and the first direction and the second direction are crossed, and the first direction and the second direction have a non-straight angle.

The shallow isolation structures 124 may extend from a top surface S1a of the stacked structure S1 toward the substrate 110 (for example, the Z-axis direction), penetrating an upper portion of the stacked structure S1, and each block (for example, B1 and B2) are divided into a plurality of sub-blocks (for example, B1a, B1b, B1c, B1d, B2a, B2b, B2c, B1d). Each of the shallow isolation structures 124 includes a substance having a dielectric constant of less than 3.9. For example, the shallow isolation structure 124 can include a low k material or an air gap. The low k material can be fluorine-doped silicon dioxide, carbon-doped oxide, porous silicon dioxide, spin-on organic polymeric dielectric, spin-on silicon based polymeric dielectric or other suitable materials. In this embodiment, the shallow isolation structure 124 penetrating through a first top conductive layer CL1a, a second top conductive layer CL1b, and a third top conductive layer CL1c (that is, three conductive layers) sequentially disposed under the top surface S1a. However, the disclosure is not limited thereto, and the shallow isolation structure 124 can penetrate through more than three conductive layers. The shallow isolation structure 124 has a bottom surface 124s that faces the upper surface 110a of the substrate 110. In a normal direction of the upper surface 110a of the substrate 110 (for example, the third direction or the Z-axis direction), a depth H1 of the shallow isolation structures 124 is smaller than a depth H2 of the conductive connecting structures 120. The depth H1 is equivalent to the distance between the top surface S1a of the stacked structure S1 and the bottom surface 124s of the shallow isolation structure 124, and the depth H2 is equivalent to the distance between the top surface S1a of the stacked structure S1 and the upper surface 110a of the substrate 110.

In some embodiments, the width W₁ of the shallow isolation structure 124 can be approximately 40-145 nm, and the depth H1 of the shallow isolation structures 124 should be larger than 130 nm.

In some embodiments, a conductive layer CL1 closest to the bottom surface 124s among the conductive layers CL1 through which the shallow isolation structures 124 penetrate has a bottom surface CL1s, and the distance between the bottom surface CL1s of the conductive layer CL1 and the upper surface 110a of the substrate 110 may be equal to or larger than the distance between the bottom surface 124s of the shallow isolation structure 124 and the upper surface 110a of the substrate 110. In this embodiment, the third top conductive layer CL1c is the closet conductive layer CL1 among the conductive layers CL1 (that is, the first top conductive layer CL1a, the second top conductive layer CL1b, and the third top conductive layer CL1c) through which the shallow isolation structures 124 penetrate. A distance D1 between the bottom surface CL1s of the third top conductive layer CL1c and the upper surface 110a of the substrate 110 is greater than a distance D2 between the bottom surface 124s of the shallow isolation structure 124 and the upper surface 110a of the substrate 110.

In some embodiments, the shallow isolation structures 124 directly contact the corresponding ones of conductive layers CL1. In the present embodiment, the shallow isolation structures 124 directly contact the corresponding first top conductive layer CL1a, the second top conductive layer CL1b, and the third top conductive layer CL1c, but the disclosure is limited thereto.

In some embodiments, the conductive layer through which the shallow isolation structures 124 penetrate may serve as a string selection line. In this embodiment, the first top conductive layer CL1a, the second top conductive layer CL1b, and the third top conductive layer CL1c may serve as the string selection lines. In other words, the shallow isolation structures 124 may penetrate through three or more than three conductive layers disposed at a top portion of the stacked structure S1, and each of the shallow isolation structures 124 separates three or more conductive layers disposed in an upper portion of the stacked structure S1 into two electrically independent string selection lines.

In this embodiment, the string select lines (for example, the first top conductive layer CL1a, the second top conductive layer CL1b, and the third top conductive layer CL1c) in the different sub-blocks B1a, B1b, B1c, B1d is separated by shallow isolation structures 124 comprising a substance having a dielectric constant of less than 3.9. When the voltage operation is performed on the string selection lines of the sub-blocks B1a, B1b, B1c, B1d, the capacitance between the string selection lines in different sub-blocks B1a, B1b, B1c and B1d can be reduced, so that the voltages of the string selection lines between different sub-blocks can be prevented from interfering with each other. For example, the interference between the voltage of the third top conductive layer CL1c at the first side 1241 of the shallow isolation structure 124 and the voltage of the third top conductive layer CL1c at the second side 1242 of the shallow isolation structure 124 may be reduced. The first side 1241 is opposite to the second side 1242. Therefore, compared with the comparative example without the shallow isolation structure having low dielectric constant material, the capacitance value between the string selection lines of different sub-blocks can be reduced by the arrangement of the shallow isolation structure 124, the charging delay time of the string selection lines of different sub-blocks can be reduced, such that the voltage of the string selection lines can be more stable, so that the string selection lines can have excellent electrical properties, and the memory device can have better performance.

Furthermore, since the shallow isolation structure 124 of the present application corresponds to a plurality of conductive layers (for example, three or more conductive layers), compared to the comparative example in which the shallow isolation structure corresponds to only one conductive layer, the generation of leakage current can be more effectively prevented during boosting.

In some embodiments, each of the intersections between the top conductive layers (eg, top conductive layers CL1a, CL1b, and CL1c) used as string select lines and the memory layers 114 may form a transistor T, and each of the intersections between the other conductive layers CL used as the word lines and the memory layers 114 can form a memory cell M. The transistor T and the memory cell M are connected in series with each other by the channel structure 120, and can form a memory cell string together.

In a second direction (for example, the Y-axis direction) parallel to the upper surface 110a of the substrate 110, the width W₁ of the shallow isolation structure 124 vertically projected on the substrate 110 is smaller than the width W₂ of the conductive connecting structure 120 vertically projected on the substrate 110. That is, the maximum width of the shallow isolation structure 124 is less than the maximum width of the conductive connecting structure 120 in a second direction (eg, the Y-axis direction) parallel to the upper surface 110a of the substrate 110. In some embodiments, the width W₁ of the shallow isolation structure 124 in the second direction is equal to or less than the width W₃ of the diameter of the channel structure 112 in the second direction. In some embodiments, the width W₁ of the shallow isolation structure 124 is, for example, 40-145 nm. In the present embodiment, the second direction (for example, the Y-axis direction) is, for example, perpendicular to the longitudinal direction of the conductive connecting structures 120 and the shallow isolation structures 124 (for example, the X-axis direction), but the present disclosure is not limited thereto, as long as a non-straight angle is between the X-axis direction and the Y-axis direction.

In this embodiment, three shallow isolation structures 124 are interposed between two adjacent conductive connecting structures 120, and one block (for example, B1) is divided into four sub-blocks (for example, B1a, B1b, B1c, B1d). However, the present disclosure is not limited thereto. In other embodiments, there may be two or more than three shallow isolation structures 124 between two adjacent conductive connecting structures 120. In comparison with the comparative example in which a plurality of conductive connecting structures 120 are used to divide a block of memory device into a plurality of sub-blocks, since the shallow isolation structures 124 are used in the present application to divide a block into a plurality of sub-blocks, the width of the shallow isolation structure 124 along the second direction (eg, the Y-axis direction) is less than the width of the conductive connecting structure 120 along the second direction (eg, the Y-axis direction), so the space occupied by the shallow isolation structures 124 in the memory device 100 is small, and the size of the memory device 100 can be reduced.

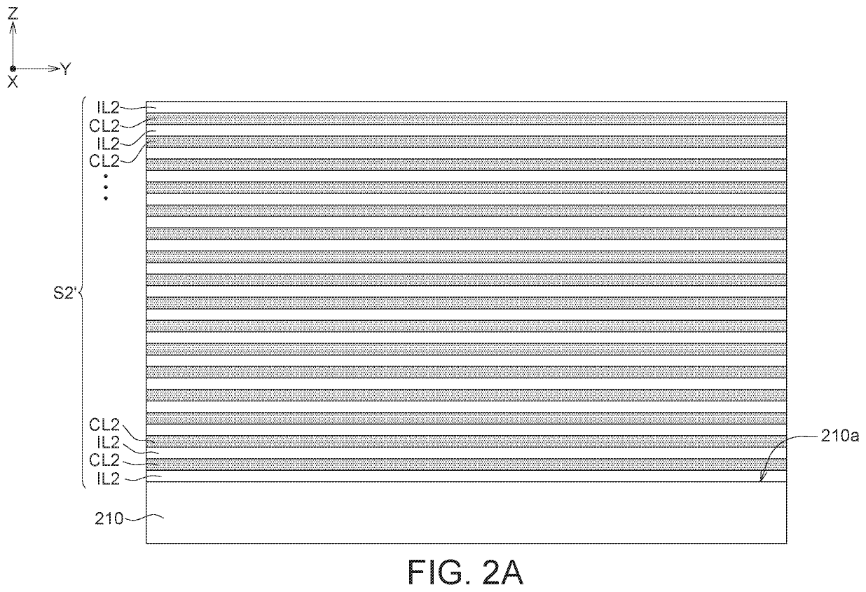

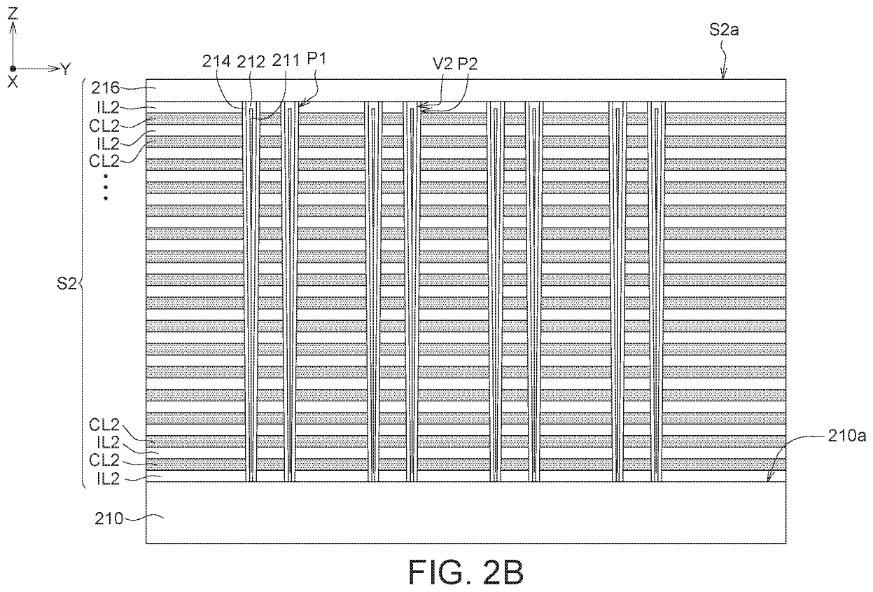

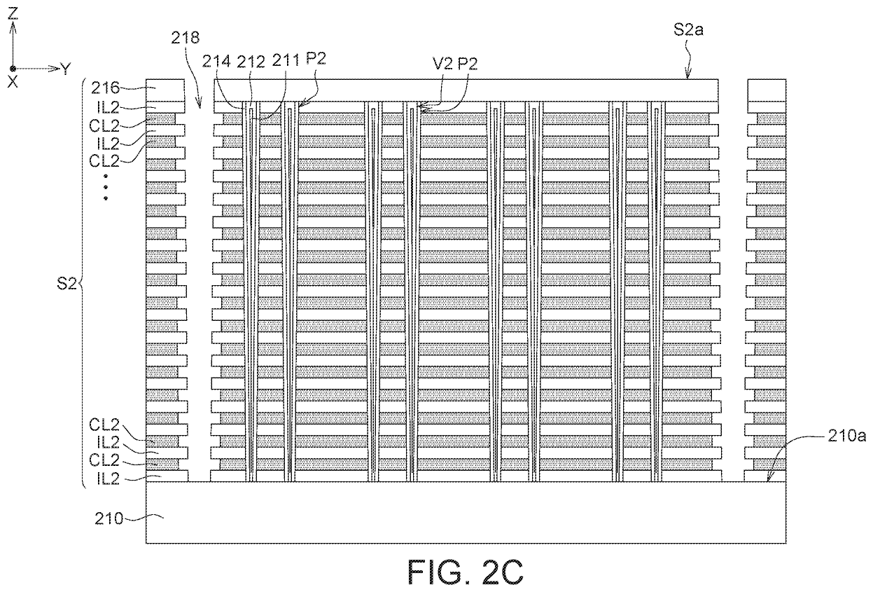

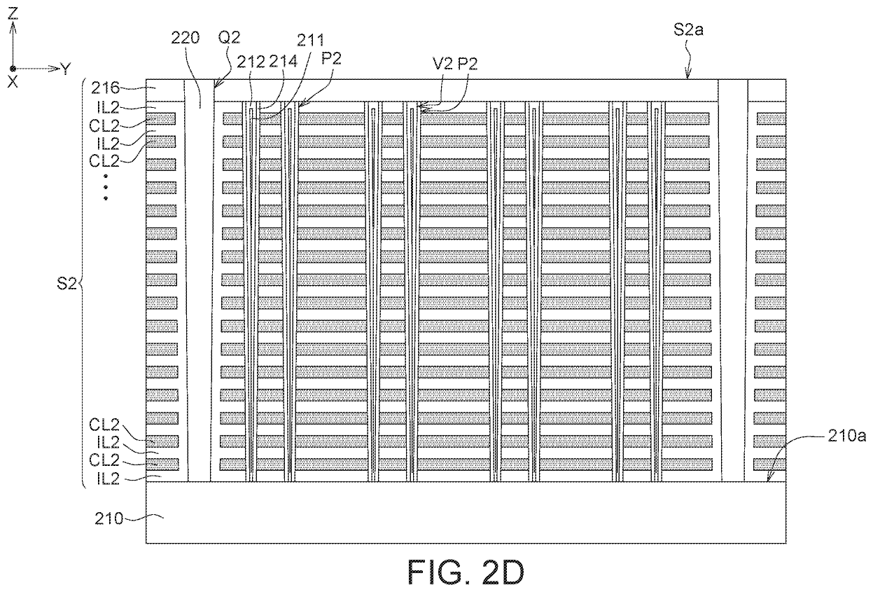

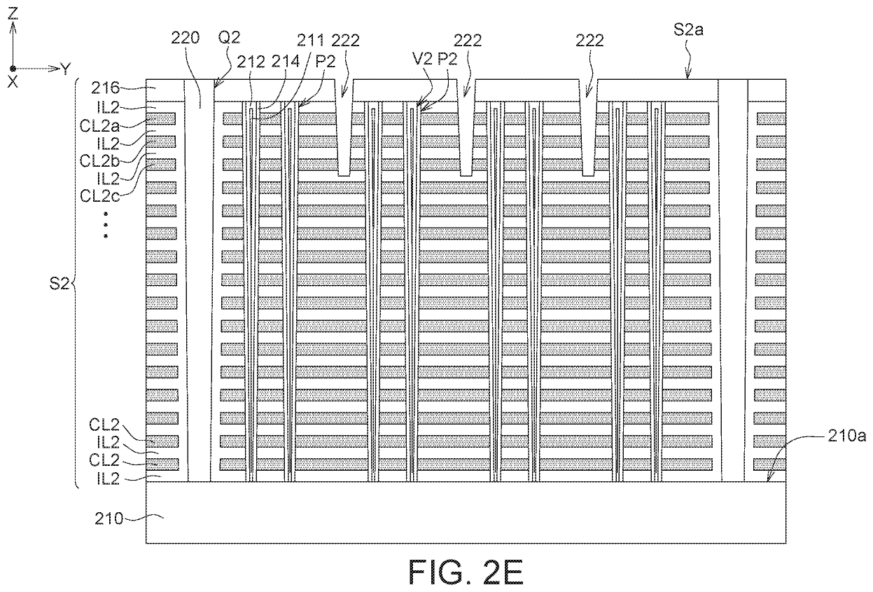

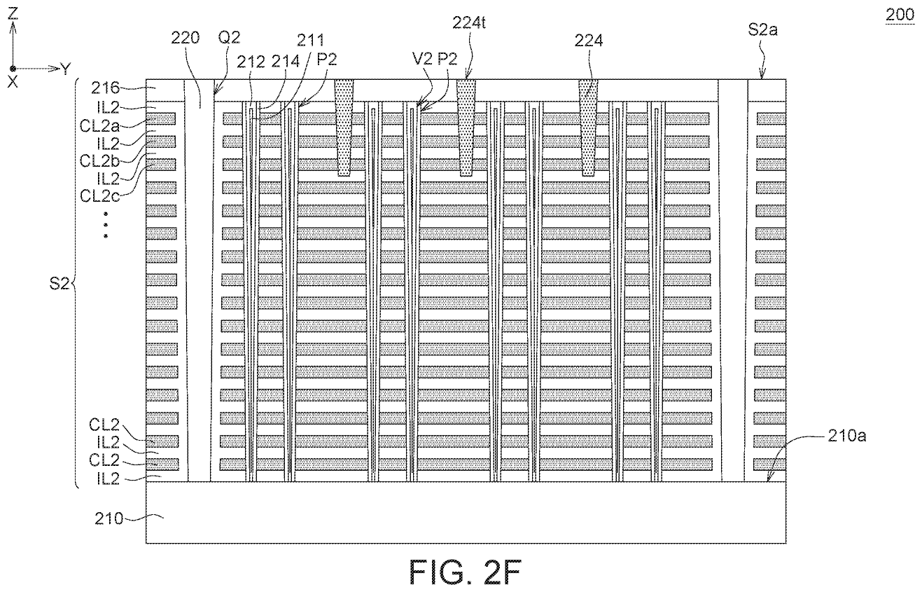

In some embodiments, the memory device 100 may be a memory device 200, 300, 400 or 500 formed by the following fabricating methods of FIGS. 2A-2F, 3, 4A-4F and 5, but the present disclosure does not limited thereto, the method for fabricating the memory device of the present disclosure also includes other suitable process methods. Further, cross-sectional views of the memory devices shown in FIGS. 2A-2F, 3, 4A-4F and 5 correspond to the cross-sectional view of the memory device 100 of FIG. 1B.

FIGS. 2A-2F are cross-sectional views showing a method for fabricating a memory device 200 in accordance with an embodiment of the present disclosure.

Referring to FIG. 2A, a substrate 210 is provided, and a stacked body S2′ is formed on the upper surface 210a of the substrate 210. The stacked body S2′ includes a plurality of insulating layers IL2 and a plurality of conductive layers CL2 alternatively stacked on the upper surface 210a of the substrate 210 in sequence (for example, by a deposition process).

In some embodiments, substrate 210 can be a silicon substrate or other suitable substrate. The insulating layers IL2 may be formed of an oxide such as silicon dioxide. The conductive layers CL2 can be doped or undoped poly-silicon or other suitable material, such as an n-type doped polysilicon layer.

Referring to FIG. 2B, a plurality of channel openings P2 penetrating through (eg, along the Z-axis direction) the stacked body S2′ are formed by etching (for example, dry etching) to expose the upper surface 210a of the substrate 210. Next, a memory material is formed on the stacked body S2′ and in the channel openings P2 by a deposition process. Then, a portion of the memory material disposed in the channel openings P2 is removed by an etching process to form a plurality of via holes V2 exposing the upper surface 210a of the substrate 210. Thereafter, a conductive material and an insulating material are filled in the via holes V2 to form a plurality of channel structures 212, a plurality of insulating posts 211 and a plurality of memory layers 214. The channel structures 212 may be formed of a doped or undoped polysilicon material. The memory layers 214 may be composed of a composite layer (ie, an ONO layer) including a silicon oxide layer, a silicon nitride layer, and a silicon oxide layer. Thereafter, the cap layer 216 covering the stacked body S2′ is formed by a deposition process, and a stacked structure S2 including the stacked body S2′ and the cap layer 216 is formed. The stacked structure S2 has a top surface S2a. The channel structures 212 penetrate through a portion of the stacked structure S2 and are electrically connected to the substrate 110. Each of the memory layers 214 surround the corresponding one of the channel structures 212.

Referring to FIG. 2C, a plurality of vertical openings 218 are formed penetrating through the stacked structure S2 by an etching process (eg, a dry etching process). In the present embodiment, the vertical openings 218 penetrate through the cap layer 216 and the stacked structure S2, and expose the upper surface 210a of the substrate 210. Next, portions of the conductive layers CL2 are removed from the vertical openings 218.

Referring to FIG. 2D, an insulating material is filled in the vertical openings 218. Thereafter, portions of the insulating material are removed to form the inner openings Q2. The inner openings Q2 penetrate through the stacked structure S2 and expose the upper surface 210a of the substrate 210. Thereafter, a conductive material is filled in the inner openings Q2 by a deposition process to form a plurality of conductive connecting structures 220. The conductive connecting structures 220 may include tungsten (W), aluminum (Al), titanium nitride (TiN), tantalum nitride (TaN), or other suitable materials.

Referring to FIG. 2E, a plurality of upper openings 222 are formed by an etching process (for example, a dry etching process). The upper openings 222 penetrate an upper portion of the stacked structure S2. The upper openings 222 are, for example, penetrating through three conductive layers (that is, the first top conductive layer CL2a, the second top conductive layer CL2b, and the third top conductive layer CL2c), but the disclosure is not limited thereto. In some embodiments, the upper openings 222 can penetrate through more than three conductive layers.

Referring to FIG. 2F, a low dielectric constant material is filled into the upper opening 222 by a deposition process to form shallow isolation structures 224 in the upper openings 222. As a result, the memory device 200 is formed. In the present embodiment, the shallow isolation structures 224 penetrate through three conductive layers (that is, the first top conductive layer CL2a, the second top conductive layer CL2b, and the third top conductive layer CL2c), but the present disclosure does not limited thereto. In some embodiments, the shallow isolation structures 224 can penetrate through more than three conductive layers. The shallow isolation structures 224 include a substance having a dielectric constant of less than 3.9. In some embodiments, the top surfaces 224t of the shallow isolation structures 224 can be coplanar with the top surface S2a of the stacked structure S2.

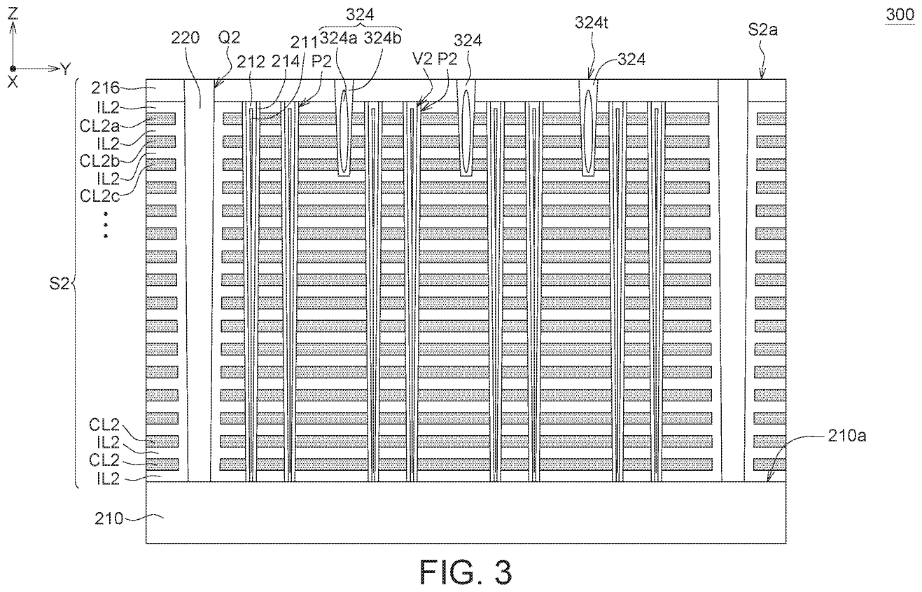

FIG. 3 is a cross-sectional view of a memory device 300 in accordance with an embodiment of the present disclosure. The method for fabricating the memory device 300 is similar to the memory device 200, the difference is in the material of the shallow isolation structures 324.

Referring to FIG. 3, after the forming steps as shown in FIGS. 2A-2E, an insulating material filled in the upper openings 222 by a deposition process to form oxide liners 324b in the upper openings 222 and air gaps 324a covered by the oxide liners 324b. In the present embodiment, the shallow isolation structures 324 penetrate through three conductive layers (that is, the first top conductive layer CL2a, the second top conductive layer CL2b, and the third top conductive layer CL2c), but the present disclosure is not limited thereto. In some embodiments, the shallow isolation structures 324 can penetrate through more than three conductive layers. In some embodiments, the top surfaces 324t of the shallow isolation structures 324 can be coplanar with the top surface S2a of the stacked structure S2.

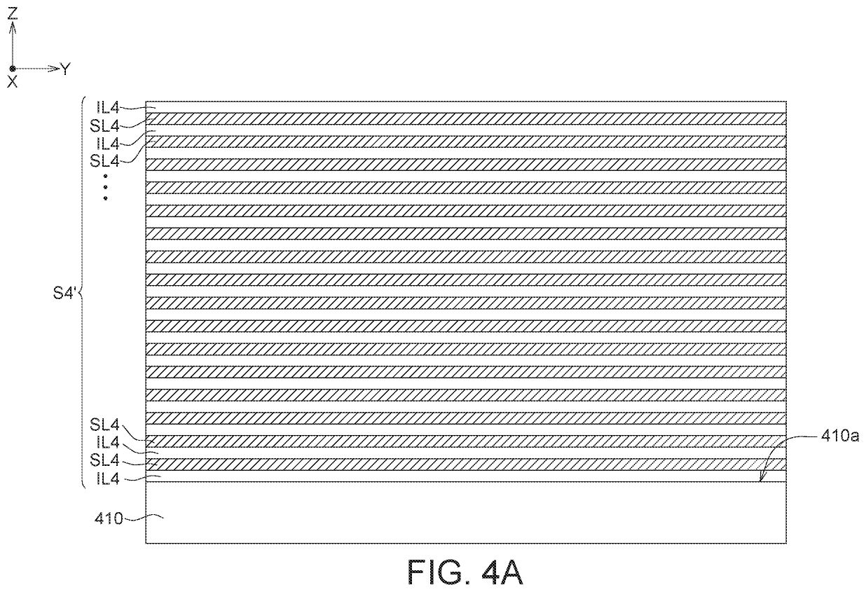

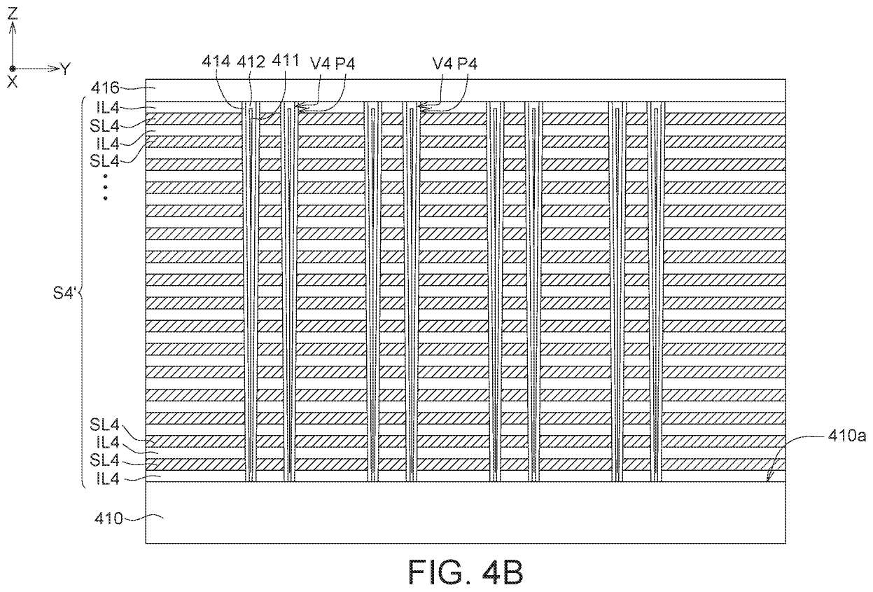

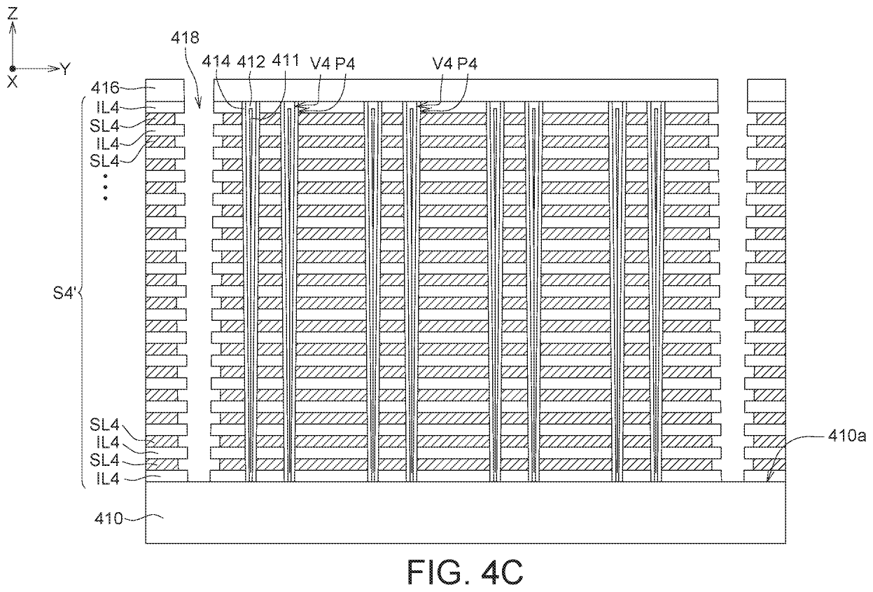

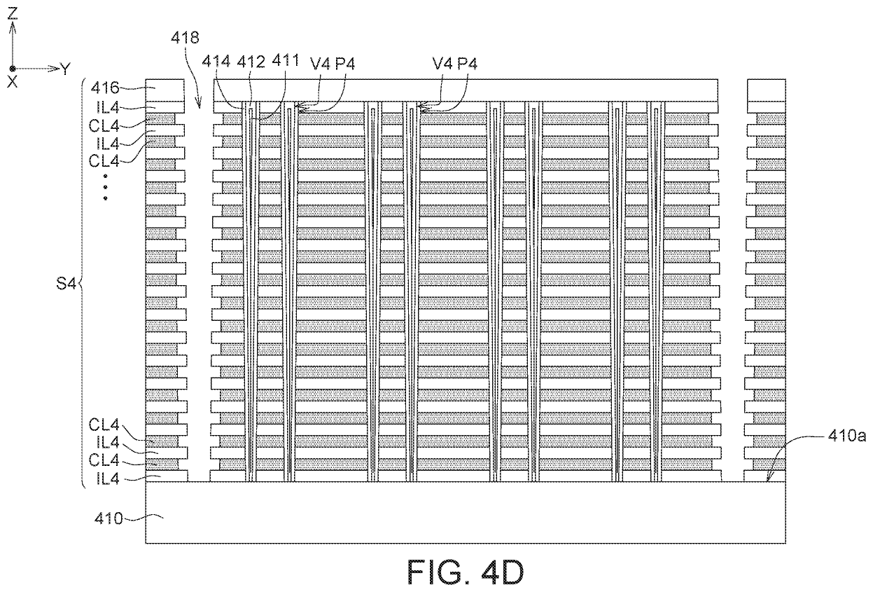

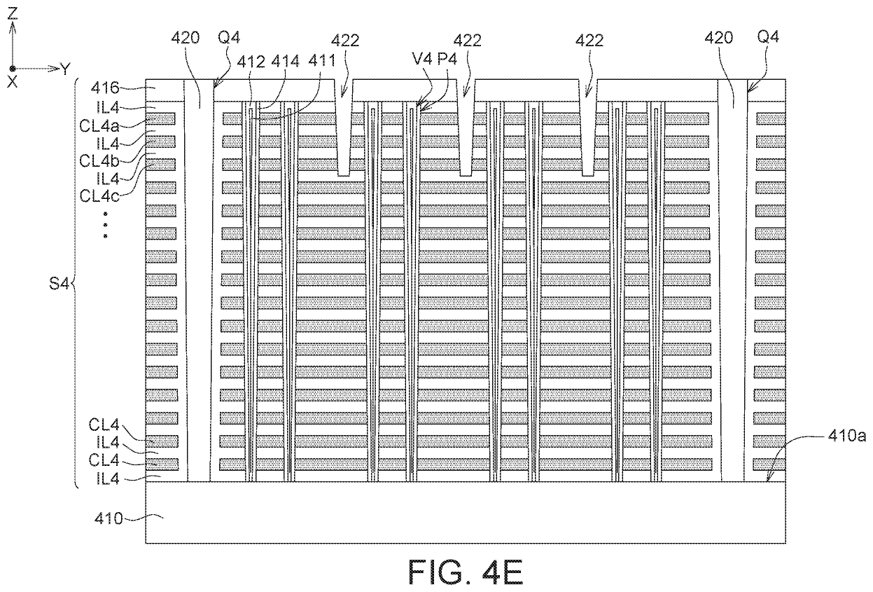

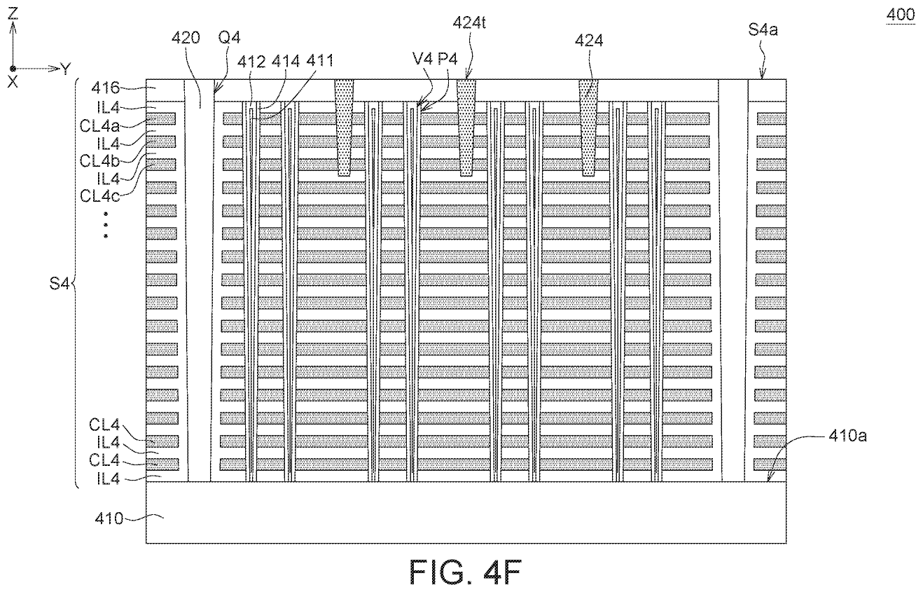

FIGS. 4A to 4F are cross-sectional views showing a method for fabricating a memory device 400 according to an embodiment of the present disclosure.

Referring to FIG. 4A, a substrate 410 is provided, and a stacked body S4′ is formed on an upper surface 410a of the substrate 410. The stacked body S4′ includes a plurality of insulating layers IL4 and a plurality of sacrificial layers SL4 alternatively stacked on the upper surface 410a of the substrate 410 in sequence (for example, by a deposition process).

In some embodiments, the substrate 410 can be a silicon substrate or other suitable substrate. The insulating layers IL4 may be formed of an oxide such as silicon dioxide. The sacrificial layers SL4 may be formed of silicon nitride (SiN).

Referring to FIG. 4B, a plurality of channel openings P4 penetrating the stacked body S4′ (e.g., along the Z-axis direction) and exposing the upper surface 410a of the substrate 410 are formed by etching (for example, dry etching). Next, a memory material is formed on the stacked body S4′ and in the channel openings P4 by a deposition process. Then, portions of the memory material disposed in the channel openings P4 are removed by an etching process to form a plurality of via holes V4 exposing the upper surface 410a of the substrate 410. Thereafter, a conductive material and a insulating material are filled in the via holes V4 to form a plurality of channel structures 412, a plurality of insulating posts 411 and a plurality of memory layers 414. The channel structures 412 may be formed of a doped or undoped polysilicon material. The memory layers 414 may be composed of a composite layer (ie, an ONO layer) including a silicon oxide layer, a silicon nitride layer, and a silicon oxide layer. The channel structures 212 penetrate through the stacked body S4′ and are electrically connected to the substrate 410. Each of memory layers 414 surrounds the corresponding one of channel structures 412. Thereafter, a cap layer 416 covering the stacked body S4′ is formed by a deposition process. The cap layer 416 may be formed of an oxide such as silicon dioxide.

Referring to FIG. 4C, a plurality of vertical openings 418 are formed penetrating through the stacked body S4′ and the cap layer 416 by an etching process (eg, a dry etching process). In the present embodiment, the vertical openings 418 expose the upper surface 410a of the substrate 410.

Referring to FIG. 4D, a pull back process is performed to remove the sacrificial layers SL4 from the vertical openings 418. The pull back process can be an isotropic etching (eg, a wet etch) and can be a highly selective etching, such as selectively etching silicon nitride without etching silicon dioxide and polysilicon.

Thereafter, a conductive material filled at positions where the sacrificial layers SL4 are removed, thereby forming conductive layers CL4 between the insulating layers IL4. As a result, the plurality of insulating layers IL4 and the plurality of conductive layers CL4 alternatively stacked on the upper surface 410a and the cap layer 416 form a stacked structure S4. The conductive layers CL4 may include tungsten (W), aluminum (Al), titanium nitride (TiN), tantalum nitride (TaN), or other suitable materials.

Referring to FIG. 2E, an insulating material is filled in the vertical openings 418. Thereafter, portions of the insulating material are removed to form inner openings Q4. The inner openings Q4 penetrating through the stacked structure S4 and expose the upper surface 410a of the substrate 410. Thereafter, a conductive material is filled in the inner openings Q4 by a deposition process to form the conductive connecting structures 420. The conductive connecting structures 420 may include tungsten (W), aluminum (Al), titanium nitride (TiN), tantalum nitride (TaN), or other suitable materials.

Thereafter, a plurality of upper openings 422 are formed by an etching process such as a dry etching process. The upper openings 422 penetrate through an upper portion of the stacked structure S4. The upper openings 422 are, for example, penetrate through three conductive layers (that is, the first top conductive layer CL4a, the second top conductive layer CL4b, and the third top conductive layer CL4c), but the disclosure is not limited thereto. In some embodiments, the upper openings 422 can penetrate through more than three conductive layers.

Referring to FIG. 4F, a low dielectric constant material is filled into the upper openings 422 by a deposition process to form shallow isolation structures 424 in the upper openings 422. As a result, the memory device 400 is formed. In the present embodiment, the shallow isolation structures 424 penetrate through the three conductive layers (that is, the first top conductive layer CL4a, the second top conductive layer CL4b, and the third top conductive layer CL4c), but the present disclosure is not limited thereto. In some embodiments, the shallow isolation structures 424 can penetrate through more than three conductive layers. The shallow isolation structures 424 include a substance having a dielectric constant of less than 3.9. In some embodiments, the top surfaces 424t of the shallow isolation structures 424 can be coplanar with the top surface S4a of the stacked structure S4.

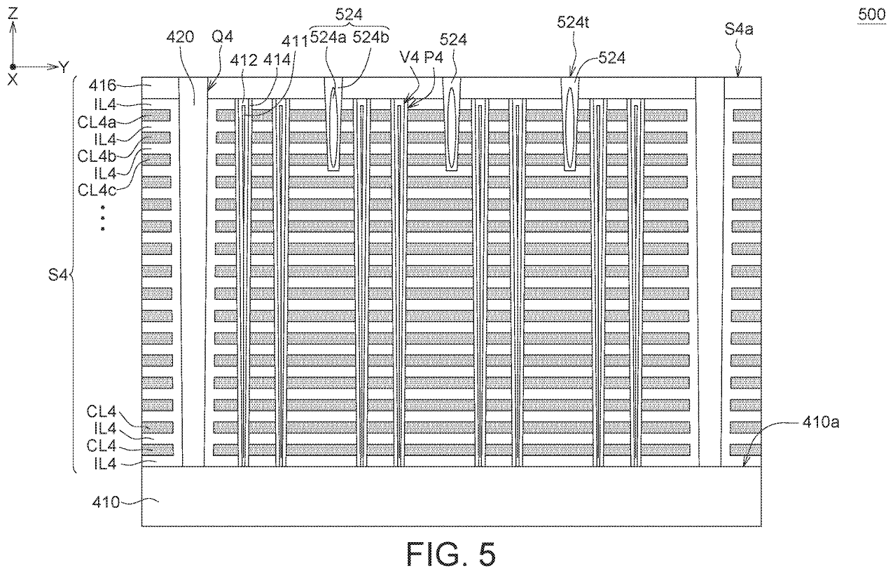

FIG. 5 is a cross-sectional view of a memory device 500 in accordance with an embodiment of the present disclosure. The memory device 500 is fabricated by methods similar to the memory device 400, and the difference is in the material of the shallow isolation structures 524.

Referring to FIG. 5, after the forming steps as shown in FIGS. 4A-4E, an insulating material is filled in the upper openings 422 by a deposition process to form oxide liners 524b in the upper openings 422 and air gaps 524a covered by the oxide liners 524b. In the present embodiment, the shallow isolation structures 524 penetrate through three conductive layers (that is, the first top conductive layer CL5a, the second top conductive layer CL5b, and the third top conductive layer CL5c), but the present disclosure is not limited thereto. In some embodiments, the shallow isolation structures 524 can penetrate through more than three conductive layers. In some embodiments, the top surfaces 524t of the shallow isolation structures 524 can be coplanar with the top surface S4a of the stacked structure S4.

The present disclosure provides a memory device and a method for fabricating the same. The memory device of the present disclosure can be applied to a 3D NAND memory device or a 3D ROM memory device.

According to an embodiment of the present disclosure, a memory device includes a substrate, a stacked structure, a plurality of channel structures, a plurality of memory layers, and a plurality of shallow isolation structures. The substrate has an upper surface. The stacked structure is disposed on the upper surface of the substrate, wherein the stacked structure includes a plurality of insulating layers and a plurality of conductive layers alternatively stacked on the upper surface. The channel structures penetrate through portions of the stacked structure and are electrically connected to the substrate. Each of the memory layers surrounds the corresponding one of the channel structures. The shallow isolation structures extend from a top surface of the stacked structure toward the substrate, wherein the shallow isolation structures comprises a substance having a dielectric constant of less than 3.9.

In comparison with a comparative example without a shallow isolation structure including a substance having low dielectric constant, since the memory device of the present disclosure includes shallow isolation structures, and each of the shallow isolation structures includes a substance having a dielectric constant of less than 3.9, the capacitance between the top conductive layers (string selection lines) on different sides (different sub-blocks) of the isolation structures can be reduced, and the charging delay time of the top conductive layers (string selection lines) of different sub-blocks can be reduced, such that the voltage of the top conductive layers (string select lines) can be more stable, so that the top conductive layers (string select lines) can have excellent electrical properties, and the memory device can have better performance.

While the disclosure has been described by way of example and in terms of the preferred embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory device, comprising:
a substrate having an upper surface;
a stacked structure disposed on the upper surface of the substrate, wherein the stacked structure comprises a plurality of insulating layers and a plurality of conductive layers alternatively stacked on the upper surface;
a plurality of channel structures penetrating through portions of the stacked structure and electrically connected to the substrate;
a plurality of memory layers surrounding corresponding ones of the channel structures; and
a plurality of shallow isolation structures extending from a top surface of the stacked structure toward the substrate, wherein each of the shallow isolation structures comprises a substance having a dielectric constant of less than 3.9.

2. The memory device according to claim 1, wherein the substance is fluorine-doped silicon dioxide, carbon-doped oxide, porous silicon dioxide, spin-on organic polymeric dielectric, spin-on silicon based polymeric dielectric or an air gap.

3. The memory device according to claim 1, wherein each of the shallow isolation structures penetrates through three or more than three of the conductive layers disposed in an upper portion of the stacked structure.

4. The memory device according to claim 3, wherein each of the shallow isolation structures separates the three or more conductive layers disposed in an upper portion of the stacked structure into two electrically independent string selection lines.

5. The memory device according to claim 1, further comprising a plurality of conductive connecting structures, wherein the conductive connecting structures penetrate through the stacked structure and electrically connected to the substrate.

6. The memory device according to claim 5, wherein the conductive connecting structures and the shallow isolation structures respectively extend along a first direction, and are disposed along a second direction on the substrate, the first direction and the second direction are parallel to the upper surface of the substrate, and the first direction and the second direction are crossed,
wherein a width of each of the shallow isolation structures in the second direction is smaller than a width of each of the conductive connecting structures in the second direction, and a depth of each of the shallow isolation structures is less than a depth of each of the conductive connecting structures in a normal direction of the upper surface of the substrate.

7. The memory device according to claim 5, wherein the conductive connecting structures divide the memory device into a plurality of blocks, and the shallow isolation structures divide each of the blocks into a plurality of sub-blocks.

8. The memory device according to claim 5, wherein two or more shallow isolation structures are between adjacent two of the conductive connecting structures.

9. The memory device according to claim 1, wherein the shallow isolation structures extend along a first direction and are disposed along a second direction on the substrate, the first direction and the second direction are parallel to the upper surface of the substrate, and a non-straight angle is between the second direction and the first direction,
wherein a width of each of the shallow isolation structures in the second direction is equal to or less than a width of each of the channel structures in the second direction.

10. The memory device according to claim 1, wherein the shallow isolation structures directly contact the corresponding ones of the conductive layers.

11. A method for fabricating a memory device, comprising:
providing a substrate having an upper surface;
forming a stacked structure disposed on the upper surface of the substrate, wherein the stacked structure comprises a plurality of insulating layers and a plurality of conductive layers alternatively stacked on the upper surface;
forming a plurality of channel structures and a plurality of memory layers penetrating through portions of the stacked structure, wherein the channel structures are electrically connected to the substrate, and the memory layers surround corresponding ones of the channel structures;
forming a plurality of upper openings penetrating through an upper portion of the stacked structure; and
forming a plurality of shallow isolation structures in the upper openings, wherein the shallow isolation structures extend from a top surface of the stacked structure toward the substrate, wherein each of the shallow isolation structures comprises a substance having a dielectric constant of less than 3.9.

12. The method according to claim 11, wherein the substance is fluorine-doped silicon dioxide, carbon-doped oxide, porous silicon dioxide, spin-on organic polymeric dielectric, spin-on silicon based polymeric dielectric or an air gap.

13. The method according to claim 11, wherein each of the shallow isolation structures penetrates through three or more than three of the conductive layers disposed in the upper portion of the stacked structure.

14. The method according to claim 13, wherein each of the shallow isolation structures separates the three or more conductive layers disposed in an upper portion of the stacked structure into two electrically independent string selection lines.

15. The method according to claim 11, further comprising forming a plurality of conductive connecting structures penetrating through the stacked structure and electrically connected to the substrate.

16. The method according to claim 15, wherein the conductive connecting structures and the shallow isolation structures respectively extend along a first direction, and are disposed along a second direction on the substrate, the first direction and the second direction are parallel to the upper surface of the substrate, and the first direction and the second direction are crossed,
wherein a width of each of the shallow isolation structures in the second direction is smaller than a width of each of the conductive connecting structures in the second direction, and a depth of each of the shallow isolation structures is less than a depth of each of the conductive connecting structures in a normal direction of the upper surface of the substrate.

17. A method for fabricating a memory device, comprising:
providing a substrate having an upper surface;
forming a stacked body disposed on the upper surface of the substrate, wherein the stacked body comprises a plurality of insulating layers and a plurality of sacrificial layers alternatively stacked on the upper surface;
forming a plurality of channel structures and a plurality of memory layers penetrating through the stacked body, wherein the channel structures are electrically connected to the substrate, and the memory layers surround corresponding ones of the channel structures;
forming a plurality of vertical openings penetrating the stacked body;
removing the sacrificial layers from the vertical openings;
forming a plurality of conductive layers at positions where the sacrificial layers are removed, such that the insulating layers and the conductive layers alternatively stacked on the upper surface form a stacked structure;
forming a plurality of upper openings penetrating through an upper portion of the stacked structure; and
forming a plurality of shallow isolation structures in the upper openings, wherein the shallow isolation structures extend from a top surface of the stacked structure toward the substrate, wherein each of the shallow isolation structures comprises a substance having a dielectric constant of less than 3.9.

18. The method according to claim 17, wherein the substance is fluorine-doped silicon dioxide, carbon-doped oxide, porous silicon dioxide, spin-on organic polymeric dielectric, spin-on silicon based polymeric dielectric or an air gap.

19. The method according to claim 17, wherein each of the shallow isolation structures penetrates through three or more than three of the conductive layers disposed in the upper portion of the stacked structure.

20. The method according to claim 19, wherein each of the shallow isolation structures separates the three or more conductive layers disposed in an upper portion of the stacked structure into two electrically independent string selection lines.
